(19) United States
(12) Patent Application Publication
(10) Pub. No.: US 2026/0103211 A1
(43) Pub. Date: Apr. 16, 2026

(54) APPARATUS AND METHOD FOR CONTROLLING DTE AND VEHICLE SYSTEM INCLUDING THE SAME

(71) Applicants: Hyundai Motor Company, Seoul (KR); Kia Corporation, Seoul (KR)

(72) Inventor: Myoung Jun Lee, Hwaseong-Si (KR)

(21) Appl. No.: 19/195,940

(22) Filed: May 1, 2025

(30) Foreign Application Priority Data
Oct. 11, 2024 (KR) 10-2024-0138950

(51) Int. Cl. B60W 50/14; B60L 58/13; B60W 50/00; H03K 3/037

(52) U.S. Cl. CPC B60W 50/14; B60L 58/13; H03K 3/037; B60L 2250/16; B60L 2260/52; B60W 2050/0083; B60W 2050/146; B60W 2510/244

(57) ABSTRACT

The present disclosure relates to a distance to empty (DTE) control apparatus and a DTE control method. The apparatus may include an interface where driving information of a vehicle is input; and a processor configured to determine a DTE of the vehicle, and the processor may be configured to set one certified fuel efficiency and multiple variable rates based on driving information of the vehicle, monitor actual fuel efficiency per unit distance in response to starting driving of the vehicle, compare the monitored actual fuel efficiency with the certified fuel efficiency to determine one of the variable rates for each unit distance, adjust the actual fuel efficiency based on the rate determined for each unit distance, and determine the DTE based on the adjusted actual fuel efficiency.

### TECHNICAL FIELD

The present disclosure relates to a vehicle control apparatus, and more specifically to a distance to empty (DTE) control apparatus and a DTE control method.

### BACKGROUND TECHNOLOGY OF THE INVENTION

An electric vehicle runs by charging electricity to a battery and using the charged electricity to drive a motor. For electric vehicles, it is important to check a battery status, such as a current battery temperature and a battery state of charge (SOC), and manage it so as to maintain the battery status above a certain level. One of the reasons for this is to identify the battery SOC in real time and inform a driver of the DTE according to the remaining battery capacity while driving.

In relation to the DTE according to the remaining battery capacity, just as internal combustion engine vehicles predict the DTE from a current fuel level and inform the driver, electric vehicles may also provide an estimate of the DTE (remaining travel distance) based on a current battery energy status (e.g., SOC) and display it on the instrument cluster, etc. for the user.

### CONTENTS OF THE INVENTION

### Problems to Be Solved

An exemplary embodiment of the present disclosure attempts to provide a distance to empty (DTE) control apparatus and method, and a vehicle using the same, capable of providing a DTE with high accuracy and stability by monitoring actual energy efficiency per unit distance to determine a rate, and by adjusting the actual energy efficiency based on the rate to determine the DTE, in response to a case where a vehicle starts driving, thereby enhancing user stability and satisfaction.

The technical objects of the present disclosure are not limited to the objects mentioned above, and other technical objects not mentioned may be clearly understood by those skilled in the art from the description of the claims.

### Means for Solving the Problem

According to one or more example embodiments of the present disclosure, a distance to empty (DTE) control apparatus may include: a communication interface configured to receive driving information of a vehicle; and a processor configured to: set, based on the driving information, a default energy efficiency of the vehicle and a plurality of energy rates; monitor, after the vehicle starts a trip, actual energy efficiency for each unit distance traveled by the vehicle; select, based on a comparison between the monitored actual energy efficiency and the default energy efficiency, an energy rate, of the plurality of energy rates, for each unit distance; adjust the actual energy efficiency based on the selected energy rate for each unit distance; determine, based on the adjusted actual energy efficiency, a DTE of the vehicle; and output, for display in the vehicle, the DTE.

The driving information may include a certified all-electric range (AER) and available energy of the vehicle. The certified AER may represent a driving range of the vehicle per recharge. The processor may be configured to set the default energy efficiency by: setting the default energy efficiency based on the certified AER and the available energy of the vehicle.

The processor may be configured to set the plurality of energy rates by: setting, based on the driving information: a first energy rate corresponding to a default energy rate of the vehicle, a second energy rate for the vehicle in a stable behavior, and a third energy rate for the vehicle in an unstable behavior.

The processor may be configured to set the first energy rate, the second energy rate, and the third energy rate by: for each unit distance, setting, based on a flip-flop logic circuit, the first energy rate, the second energy rate, and the third energy rate.

The flip-flop logic circuit may include: a reset-set (RS) flip-flop configured to output a signal for selecting the energy rate for each unit distance; a first AND gate connected to a first input terminal of the RS flip-flop. The first AND gate may be configured to output, based on receiving the actual energy efficiency as an input value, an output value to the first input terminal of the RS flip-flop. The flip-flop logic may further include a second AND gate connected to a second input terminal of the RS flip-flop. The second AND gate may be configured to output, based on receiving the actual energy efficiency as an input value, an output value to the second input terminal of the RS flip-flop.

The processor may be configured to select the energy rate by performing one of: selecting the third energy rate for each unit distance based on the actual energy efficiency being equal to a first reference energy rate at any time while the vehicle traverses the unit distance; selecting the second energy rate for each unit distance based on the actual energy efficiency being equal to a second reference energy rate at any time while the vehicle traverses the unit distance; or selecting the first energy rate for each unit distance based on the actual energy efficiency being one of: never equal to the first reference energy rate or the second reference energy rate while the vehicle traverses the unit distance, or equal to the first reference energy rate at least once and equal to the second reference energy rate at least once while the vehicle traverses the unit distance.

The processor may be configured to adjust the actual energy efficiency by performing one of: adjusting, based on the first energy rate being selected, the actual energy efficiency to maintain or change an applied energy rate of the actual energy efficiency to the default energy rate of the vehicle; adjusting, based on a higher reference rate associated with the second energy rate being selected, the actual energy efficiency to increase the applied energy rate of the actual energy efficiency; or adjusting, based on a lower reference rate associated with the second energy rate being selected, the actual energy efficiency to decrease the applied energy rate of the actual energy efficiency.

The processor may be configured to monitor the actual energy efficiency for each unit distance by: determining, after the vehicle starts the trip, whether a travel distance of the vehicle reaches a first unit distance; recording, based on the travel distance of the vehicle reaching the first unit distance, the actual energy efficiency for the first unit distance; determining whether the travel distance of the vehicle reaches a second unit distance; recording, based on the travel distance of the vehicle reaching the second unit distance, the actual energy efficiency for the second unit distance; determining whether the travel distance of the vehicle reaches a third unit distance; and recording, based on the travel distance of the vehicle reaching the third unit distance, the actual energy efficiency for the third unit distance.

The processor may be further configured to: after the determining of the DTE, initialize, based on the vehicle ending the trip, selection of the plurality of energy rates for each unit distance.

The processor may be further configured to repeatedly perform a process that includes: selecting an updated energy rate of the plurality of energy rates for each unit distance based on the vehicle starting a new trip after the initialization of selection of the plurality of energy rates; adjusting an updated actual energy efficiency based on the updated energy rate selected for each unit distance; and determining an updated DTE based on the adjusting of the updated actual energy efficiency.

According to one or more example embodiments of the present disclosure, a vehicle system may include a distance to empty (DTE) control apparatus and a display device. The DTE control apparatus may be configured to: set, based on driving information of a vehicle, a default energy efficiency of the vehicle and a plurality of energy rates; monitor, after the vehicle starts a trip, actual energy efficiency for each unit distance traveled by the vehicle; select, based on a comparison between the monitored actual energy efficiency and the default energy efficiency, an energy rate, of the plurality of energy rates, for each unit distance; adjust the actual energy efficiency based on the selected energy rate for each unit distance; and determine, based on the adjusted actual energy efficiency, a DTE of the vehicle. The display device may be configured to display the DTE.

According to one or more example embodiments of the present disclosure, a method performed by an apparatus of a vehicle may include: setting, by a processor and based on driving information of the vehicle, a default energy efficiency of the vehicle and a plurality of energy rates; monitoring, by the processor and after the vehicle starts a trip, actual energy efficiency per unit distance for each unit distance traveled by the vehicle; selecting, by the processor and based on a comparison between the monitored actual energy efficiency and the default energy efficiency, an energy rate, of the plurality of energy rates, for each unit distance; adjusting, by the processor, the actual energy efficiency based on the selected energy rate for each unit distance; determining, by the processor and based on the adjusted actual energy efficiency, a distance to empty (DTE) of the vehicle; and outputting, for display in the vehicle, the DTE.

The driving information may include a certified all-electric range (AER) and available energy of the vehicle. The certified AER may represent a driving range of the vehicle per recharge. Setting the default energy efficiency may include: setting the default energy efficiency based on the certified AER and the available energy of the vehicle.

Setting the plurality of energy rates may include: setting, based on the driving information: a first energy rate corresponding to a default energy rate of the vehicle, a second energy rate for the vehicle in a stable behavior, and a third energy rate for the vehicle in an unstable behavior.

Setting the first energy rate, the second energy rate, and the third energy rate may include: for each unit distance, setting, based on a flip-flop logic circuit, the first energy rate, the second energy rate, and the third energy rate.

Selecting the energy rate may include performing one of: selecting the third energy rate for each unit distance based on the actual energy efficiency being equal to a first reference energy rate at any time while the vehicle traverses the unit distance; selecting the second energy rate for each unit distance based on the actual energy efficiency being equal to a second reference energy rate at any time while the vehicle traverses the unit distance; or selecting the first energy rate for each unit distance based on the actual energy efficiency being one of: never equal to the first reference energy rate or the second reference energy rate while the vehicle traverses the unit distance, or equal to the first reference energy rate at least once and equal to the second reference energy rate at least once while the vehicle traverses the unit distance.

Adjusting the actual energy efficiency may include performing one of: adjusting, based on the first energy rate being selected, the actual energy efficiency to maintain or change an applied energy rate of the actual energy efficiency to the default energy rate of the vehicle; adjusting, based on a higher reference rate associated with the third energy rate being selected, the actual energy efficiency to increase the applied energy rate of the actual energy efficiency; or adjusting, based on a lower reference rate associated with the third energy rate being selected, the actual energy efficiency to decrease the applied energy rate of the actual energy efficiency.

Monitoring the actual energy efficiency for each unit distance may include: determining, after the vehicle starts the trip, whether a travel distance of the vehicle reaches a first unit distance; recording, based on the travel distance of the vehicle reaching the first unit distance, the actual energy efficiency for the first unit distance; determining whether the travel distance of the vehicle reaches a second unit distance; recording, based on the travel distance of the vehicle reaching the second unit distance, the actual energy efficiency for the second unit distance; determining whether the travel distance of the vehicle reaches a third unit distance; and recording, based on the travel distance of the vehicle reaching the third unit distance, the actual energy efficiency for the third unit distance.

The method may further include: after the determining of the DTE, initializing, based on the vehicle ending the trip, selection of the plurality of energy rates for each unit distance.

The method may further include repeatedly performing a process that includes: selecting an updated energy rate of the plurality of energy rates for each unit distance based on the vehicle starting a new trip after the initializing of selection of the plurality of energy rates; adjusting an updated actual energy efficiency based on the update energy rate selected for each unit distance; and determining an updated DTE based on the adjusting of the updated actual energy efficiency.

According to the present technique, in response to a case where a vehicle starts driving, a DTE with high accuracy and stability may be provided by monitoring actual fuel efficiency per unit distance to determine a rate, and by adjusting the actual fuel efficiency based on the rate to determine the DTE, thereby enhancing user stability and satisfaction.

### Effect of Invention

Furthermore, according to the present technique, actual fuel efficiency of a user may be monitored by applying a flip-flop logic, which is a logic circuit, and a variable rate applied to the logic circuit according to a behavior of the actual fuel efficiency may be applied to a rate that suits a user's driving pattern, thereby improving the accuracy of a DTE and providing a stable behavior.

According to the present technique, optimized behavior stability of the DTE that can resolve customer complaints about inaccuracy of the DTE may also be provided by predicting the DTE in consideration of various driving patterns of a customer.

Furthermore, various effects which may be directly or indirectly identified through the present specification may be provided.

### BRIEF DESCRIPTION OF THE DRAWING

FIG. 1 shows an example vehicle system including a distance to empty (DTE) control apparatus.

FIG. 2 shows a block diagram showing a consideration of an example DTE control apparatus.

FIG. 3 shows a block diagram for describing a processor of an example DTE control apparatus.

FIG. 4 shows a graph for describing a variable rate setting process of an example DTE control apparatus.

FIG. 5 and FIG. 6 show views for describing a logic of a flip-flop logic circuit for rate determination of an example DTE control apparatus.

FIG. 7 and FIG. 8 each show a flowchart for describing a DTE control method for an example DTE control apparatus.

FIG. 9 shows an example computing system for a vehicle.

### DETAILED DESCRIPTION FOR CARRYING OUT THE INVENTION

Hereinafter, some example embodiment(s) of the present disclosure will be described in detail with reference to exemplary drawings. It should be noted that in adding reference numerals to constituent elements of each drawing, the same constituent elements include the same reference numerals as possible even though they are indicated on different drawings. In describing one or more example embodiment(s) of the present disclosure, when it is determined that a detailed description of the well-known configuration or function associated with the example embodiment(s) of the present disclosure may obscure the gist of the present disclosure, it will be omitted.

In describing constituent elements according to one or more example embodiment(s) of the present disclosure, terms such as first, second, A, B, (a), and (b) may be used. These terms are only for distinguishing the constituent elements from other constituent elements, and the nature, sequences, or orders of the constituent elements are not limited by the terms. Furthermore, all terms used herein including technical scientific terms have the same meanings as those which are generally understood by those skilled in the technical field to which an example embodiment of the present disclosure pertains (those skilled in the art) unless they are differently defined. Terms defined in a generally used dictionary shall be construed to have meanings matching those in the context of a related art, and shall not be construed to have idealized or excessively formal meanings unless they are clearly defined in the present specification.

For purposes of this application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, and C”, “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

A method of determining a distance to empty (DTE) may involve obtaining consumed energy of an electric vehicle battery and determining the DTE through energy efficiency and remaining available energy.

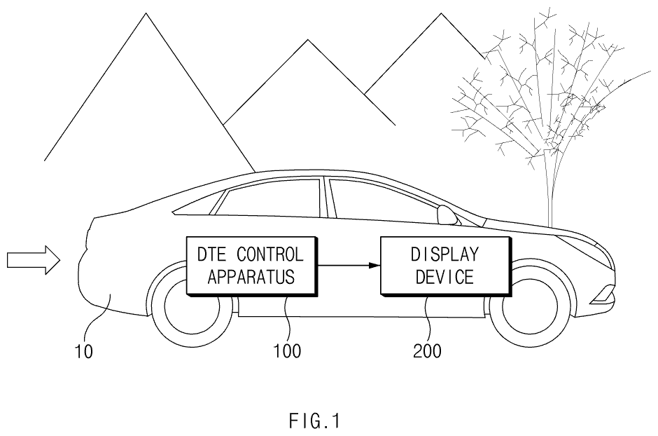

Hereinafter, one or more example embodiments of the present disclosure will be described in detail with reference to FIG. 1 to FIG. 9.

FIG. 1 shows an example vehicle system including a distance to empty (DTE) control apparatus.

As shown in FIG. 1, the vehicle system according to the present disclosure may include a display device 200 configured to display a DTE corresponding to driving information of a vehicle 10, and a DTE control apparatus 100 configured to determine the DTE of the vehicle 10.

The DTE control apparatus 100 may be configured to set one certified energy efficiency and multiple variable rates (also referred to as energy rates or variable energy rates) based on driving information of the vehicle 10, monitor actual energy efficiency (e.g., instantaneous energy efficiency) for each unit distance traveled, in response to starting the vehicle (e.g., after the vehicle starts moving or starts a trip), compare the monitored actual energy efficiency with the certified energy efficiency to determine one of the variable rates for each unit distance, adjust the actual energy efficiency based on the rate determined for each unit distance, and determine the DTE based on the adjusted actual energy efficiency (also referred to as the adjusted energy efficiency).

Herein, the DTE control apparatus 100 may be configured to set the certified energy efficiency based on a certified all-electric range (AER) and the available energy (e.g., SOC) of the vehicle. The AER may represent a distance that the vehicle is (e.g., rated to be) capable of driving with a fully charged battery. In other words, the AER may be the driving range (e.g., the maximum driving range) of the vehicle per recharge.

Furthermore, the DTE control apparatus 100 may be configured to set a plurality of variable rates including a first rate corresponding to a default rate, a second rate corresponding to a rate in response to a case where the vehicle is in a stable behavior (e.g., when the vehicle is cruising at a substantially constant speed), and a third rate corresponding to a rate in response to a case where the vehicle is in an unstable behavior (e.g., a high energy event or a low energy event, such as acceleration, deceleration, climbing an incline, descending a downhill slope, etc.), based on driving information of the vehicle.

Furthermore, the DTE control apparatus 100 may be configured to check whether a travel distance of the vehicle reaches a (N−1)-th unit distance after the vehicle starts moving (e.g., starts a trip), and record the actual energy efficiency for the (N−1)-th unit distance after the vehicle reaches the (N−1)-th unit distance. The DTE control apparatus 100 may be configured to check whether the travel distance of the vehicle reaches a N-th unit distance, and record the actual energy efficiency for the N-th unit distance after the vehicle reaches the N-th unit distance. The DTE control apparatus 100 may be configured to check whether a travel distance of the vehicle reaches a (N+1)-th unit distance, and record the actual energy efficiency for the (N+1)-th unit distance after the vehicle reaches the (N+1)-th unit distance.

Furthermore, the DTE control apparatus 100 may be configured to determine one of a first rate (also referred to as a first energy rate) corresponding to a default rate, a second rate (also referred to as a second energy rate) corresponding to a rate in response to a case where the vehicle is in a stable behavior, and a third rate (also referred to as a third energy rate) corresponding to a rate in response to a case where the vehicle is in an unstable behavior for each unit distance, based on logic according to a flip-flop logic circuit.

Furthermore, the DTE control apparatus 100 may be configured to determine (e.g., select) the third rate for each unit distance if a variable line of the actual energy efficiency touches a first rate line (also referred to as a first reference energy rate) at the unit distance (e.g., if the actual energy efficiency matches the first rate while the vehicle traverses the unit distance) based on an actual energy efficiency change graph according to the travel distance of the vehicle. The actual energy efficiency change graph may include a reference line corresponding to the certified energy efficiency, first rate lines (also referred to as a first reference energy rate, for example, including a higher reference rate and a lower reference rate) that are each positioned above and below the reference line and running parallel to the reference line, and second rate lines (also referred to as a second reference energy rate, for example, including a higher reference rate and a lower reference rate) that are each positioned between the reference line and one of the first rate lines. The DTE control apparatus 100 may be further configured to determine (e.g., select) the second rate for each unit distance if the variable line of the actual energy efficiency touches a second rate line for the unit distance (e.g., if the actual energy efficiency matches the second rate while the vehicle traverses the unit distance). The DTE control apparatus 100 may be further configured to determine (e.g., select) the first rate for each unit distance if the variable line of the actual energy efficiency touches neither the first rate line nor the second rate line (e.g., if the actual energy efficiency never matches the first rate and never matches the second rate at any time while the vehicle traverses the unit distance), or the variable line of the actual energy efficiency touches both the first and second rate lines (e.g., if the actual energy efficiency matches both the first rate and the second rate while the vehicle traverses the unit distance).

Furthermore, the DTE control apparatus 100 may be configured to adjust the actual energy efficiency to maintain or change a current applied rate (also referred as a current applied energy rate or an applied energy rate) of the actual energy efficiency to the default rate if the rate determined (e.g., selected) for each unit distance is the first rate, adjust the actual energy efficiency to increase the current applied rate of the actual energy efficiency in response to a case where the rate determined (e.g., selected) for each unit distance is the second rate, and adjust the actual energy efficiency to decrease the current applied rate of the actual energy efficiency in response to a case where the rate determined (e.g., selected) for each unit distance is the third rate.

Next, the DTE control apparatus 100 may be configured to repeatedly perform a process of determining (e.g., selecting) one of a plurality of variable rates for each unit distance in response to a case where the vehicle starts driving again after initialization of the rate, adjusting the actual energy efficiency based on the rate determined (e.g., selected) for each unit distance, and determining the DTE based on the adjusted actual energy efficiency.

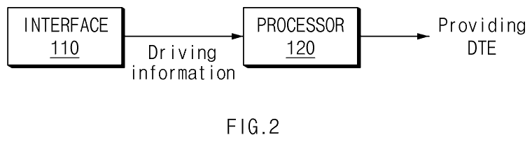

FIG. 2 shows a block diagram showing a consideration of an example DTE control apparatus.

As shown in FIG. 2, the DTE control apparatus according to the present disclosure may be configured to include an interface 110 into which driving information of the vehicle is input, and a processor 120 configured to determine a DTE of the vehicle. The interface (also referred to as a communication interface) 110 may send the driving information to the processor 120. The interface 110 may be a data port, a data interface, a data receiver, a data transceiver, a signal receiver, a signal transceiver, a user interface, etc.

The processor 120 may be configured to set (e.g., determine) certified energy efficiency (also referred to as default energy efficiency) and multiple variable rates based on the driving information of the vehicle, monitor actual energy efficiency for each unit distance after the vehicle starts moving (e.g., starts a trip), compare the monitored actual energy efficiency with the certified energy efficiency to determine (e.g., select) one of the variable rates (e.g., variable energy efficiency rates) for each unit distance, adjust the actual energy efficiency based on the rate determined (e.g., selected) for each unit distance traveled by the vehicle, and determine the DTE based on the adjusted actual energy efficiency.

Herein, the processor 120 may be configured to set the certified energy efficiency based on a certified all-electric range (AER), which is a distance at which it can be driven, in a case where a battery is fully charged, and the actual available energy.

According to the present disclosure, one of the certified AER and the certified energy efficiency according to the actual available energy may be selected.

For example, in a case of 410 km/64kWh, it may be selected as 6.4 [km/kWh], and with this energy efficiency, a user may be guaranteed a same DTE every time it is fully charged.

Furthermore, the processor 120 may be configured to set a plurality of variable rates including a first rate corresponding to a default rate, a second rate corresponding to a rate in response to a case where the vehicle is in a stable behavior, and a third rate corresponding to a rate in response to a case where the vehicle is in an unstable behavior, based on driving information of the vehicle.

For example, the processor 120 may be configured to set the certified energy efficiency as a reference line in response to a case where a change in actual energy efficiency according to the travel distance of the vehicle is expressed in a graph, set first rate lines parallel to upper and lower portions of the reference line to set an application range of the third rate, and set second rate lines parallel to the upper and lower portions of the reference line between the reference line and the first rate line to set application ranges of the first and second rates.

In the instant case, the processor 120 may be configured to set a third rate to be applied in response to a case where a variable line of the actual energy efficiency is in contact with the first rate line on a basis of the variable line of the actual energy efficiency that is variable based on the reference line of the certified energy efficiency, set a second rate to be applied in response to a case where the variable line of the actual energy efficiency is in contact with the second rate line, and set a first rate to be applied in response to a case where the variable line of the actual energy efficiency is not in contact with either the first or second rate lines or is in contact with both of them.

Furthermore, in a case of monitoring the actual energy efficiency, the processor 120 may be configured to check whether a travel distance of the vehicle reaches a (N−1)-th unit distance after the vehicle starts driving, record the actual energy efficiency for the (N−1)-th unit distance in response to a case where the vehicle reaches the (N−1)-th unit distance, check whether the travel distance of the vehicle reaches a N-th unit distance, record the actual energy efficiency for the N-th unit distance in response to a case where the vehicle reaches the N-th unit distance, and check whether a travel distance of the vehicle reaches a (N+1)-th unit distance, and record the actual energy efficiency for the (N+1)-th unit distance in response to a case where the vehicle reaches the (N+1)-th unit distance.

Herein, in the case of monitoring the actual energy efficiency, the processor 120 may be configured to stop recording the actual energy efficiency for a unit distance in response to ending vehicle driving.

For example, the processor 120 may be configured to set all unit distances to a same distance, and may set each unit distance to N km (where N is a natural number).

Next, in a case of determining (e.g., selecting) the rate for each unit distance, the processor 120 may be configured to obtain an actual energy efficiency (e.g., instantaneous energy efficiency) corresponding to a N-th unit distance, compare the actual energy efficiency corresponding to the N-th unit distance with the certified energy efficiency to determine (e.g., select) a rate corresponding to the N-th unit distance, and in response to obtaining an actual energy efficiency corresponding to the (N+1)-th unit distance, compare the actual energy efficiency corresponding to the (N+1)-th unit distance with the certified energy efficiency to determine (e.g., select) a rate corresponding to the (N+1)-th unit distance.

Next, in a case of determining (e.g., selecting) a rate for each unit distance, the processor 120 may be configured to determine (e.g., select) one of a first rate corresponding to a default rate, a second rate corresponding to a rate in response to a case where the vehicle is in a stable behavior, and a third rate corresponding to a rate in response to a case where the vehicle is in an unstable behavior for each unit distance, based on logic according to a flip-flop logic circuit.

For example, the flip-flop logic circuit may include an reset-set (RS) flip-flop configured to output a signal for determining (e.g., selecting) a rate, a first AND gate connected to a first input terminal of the RS flip-flop and configured to output an output value according to an input value of the actual energy efficiency to the first input terminal of the RS flip-flop, and a second AND gate connected to a second input terminal of the RS flip-flop and configured to output an output value according to an input value of the actual energy efficiency to the second input terminal of the RS flip-flop.

Herein, the RS flip-flop may include a first input terminal connected to an output terminal of the first AND gate, a second input terminal connected to an output terminal of the second AND gate, a clock input terminal into which a clock signal is input, a first output terminal that outputs a first signal as a signal for determining (e.g., selecting) a rate, and a second output terminal that outputs a second signal, which is an inversion of the first signal, as the signal for determining (e.g., selecting) the rate.

Furthermore, the first AND gate may include a first input terminal to which a first input value of the actual energy efficiency is input, a second input terminal connected to the second output terminal of the RS flip-flop to which a second signal is input, and an output terminal connected to the first input terminal of the RS flip-flop, and the second energy efficiency is input, a second input terminal connected to the first output terminal of the RS flip-flop to which a first signal is input, and an output terminal connected to the second input terminal of the RS flip-flop.

Furthermore, in a case of determining (e.g., selecting) a rate for each unit distance, the processor 120 may be configured to determine (e.g., select) the third rate for each unit distance if a variable line of the actual energy efficiency (e.g., the instantaneous energy efficiency) touches a first rate line at each unit distance (e.g., if the actual energy efficiency is equal to the first rate at any time while the vehicle traverses the unit distance) based on an actual energy efficiency change graph according to the travel distance of the vehicle. The actual energy efficiency change graph may include a reference line corresponding to the certified energy efficiency, first rate lines that are each positioned above and below the reference line and running parallel to the reference line, and second rate lines that are each positioned between the reference line and one of the first rate lines. The processor 120 may be further configured to determine (e.g., select) the second rate for the unit distance if the variable line of the actual energy efficiency touches a second rate line (e.g., if the actual energy efficiency matches the second rate while the vehicle traverses the unit distance). The DTE control apparatus 100 may be further to determine (e.g., select) the first rate for the unit distance if the variable line of the actual energy efficiency touch es neither the first rate line nor the second rate line (e.g., if the actual energy efficiency never matches the first rate and never matches the second rate at any time while the vehicle traverses the unit distance), or the variable line of the actual energy efficiency touches both the first and second rate lines (e.g., if the actual energy efficiency matches both the first rate and the second rate while the vehicle traverses the unit distance).

The processor 120 may be configured to adjust the actual energy efficiency to lower a current applied rate of the actual energy efficiency for the unit distance if the third rate is determined (e.g., selected) for the unit distance, adjust the actual energy efficiency to raise the current applied rate of the actual energy efficiency for the unit distance if the second rate is determined (e.g., selected) for the unit distance, and adjust the actual energy efficiency to maintain or change the current applied rate of the actual energy efficiency for the unit distance to a default rate if the first rate is determined (e.g., selected) for the unit distance.

Then, in a case of adjusting the actual energy efficiency, the processor 120 may be configured to adjust the actual energy efficiency to maintain or change a current applied rate of the actual energy efficiency to the default rate if the rate determined (e.g., selected) for each unit distance is the first rate, adjust the actual energy efficiency to increase the current applied rate of the actual energy efficiency if the rate determined (e.g., selected) for each unit distance is the second rate, and adjust the actual energy efficiency to decrease the current applied rate of the actual energy efficiency if the rate determined (e.g., selected) for each unit distance is the third rate.

Next, in a case of determining the drivable distance, the processor 120 may be configured to determine a distance to empty (DTE) per unit distance based on the actual energy efficiency adjusted for each unit distance, and provide a total DTE corresponding to driving of a vehicle based on the DTE per unit distance (e.g., the adjusted DTE per unit distance).

Furthermore, the processor 120 may be configured to determine the DTE and then, remove and initialize the rate determined (e.g., initialize selection of the one or more rates or energy rates) for each unit distance in response to ending vehicle driving (e.g., at the end of a trip).

Herein, the processor 120 may be configured to repeatedly perform a process of determining (e.g., selecting) one of a plurality of variable rates for each unit distance if the vehicle starts driving again (e.g., if the vehicle starts a new trip) after initialization of the rate, adjusting the actual energy efficiency based on the rate determined (e.g., selected) for each unit distance, and determining the DTE based on the adjusted actual energy efficiency.

As such, according to the present disclosure, if a vehicle starts driving (e.g., starts a trip), a DTE with high accuracy and stability may be provided by monitoring actual energy efficiency per unit distance to determine (e.g., select) a rate, and by adjusting the actual energy efficiency based on the rate to determine the DTE, thereby enhancing user stability and satisfaction.

Furthermore, according to the present disclosure, actual energy efficiency of a user may be monitored by applying a flip-flop logic, which is a logic circuit, and a variable rate applied to the logic circuit according to a behavior of the actual energy efficiency may be applied to a rate that suits a user's driving pattern, thereby improving the accuracy of a DTE and providing a stable behavior.

Furthermore, according to the present disclosure, optimized behavior stability of a DTE that can resolve customer complaints about inaccuracy of the DTE may also be provided by predicting the DTE in consideration of various driving patterns of a customer.

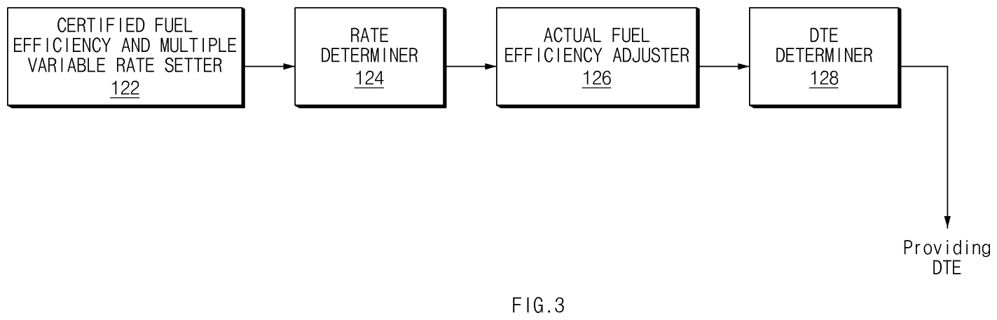

FIG. 3 shows a block diagram for describing a processor of an example DTE control apparatus.

As shown in FIG. 3, the processor according to the present disclosure may be configured to include an certified energy efficiency and multiple variable rate setter 122 configured to set one certified energy efficiency and multiple variable rates based on driving information of the vehicle, a rate determiner 124 configured to monitor actual energy efficiency for each unit distance in response to starting vehicle driving and determine a rate for each unit distance, an actual energy efficiency adjuster 126 configured to adjust actual energy efficiency based on the rate determined for each unit distance, and a DTE determiner 128 configured to determine a DTE based on the adjusted actual energy efficiency.

The certified energy efficiency and multiple variable rate setter 122 may be configured to set the certified energy efficiency based on the certified AER, which is a distance at which it can be driven after a battery is fully charged, and the actual available energy, and set a plurality of variable rates including a first rate corresponding to a default rate, a second rate corresponding to a rate if the vehicle is in a stable behavior, and a third rate corresponding to a rate if the vehicle is in an unstable behavior, based on driving information of the vehicle.

Furthermore, the rate determiner 124 may be configured to determine one of a first rate corresponding to a default rate, a second rate corresponding to a rate if the vehicle is in a stable behavior, and a third rate corresponding to a rate if the vehicle is in an unstable behavior for each unit distance, based on logic according to a flip-flop logic circuit.

Then, the actual energy efficiency adjuster 126 may be configured to adjust the actual energy efficiency to maintain or change a current applied rate of the actual energy efficiency to the default rate if the rate determined for each unit distance is the first rate, adjust the actual energy efficiency to increase the current applied rate of the actual energy efficiency if the rate determined for each unit distance is the second rate, and adjust the actual energy efficiency to decrease the current applied rate of the actual energy efficiency the rate determined for each unit distance is the third rate.

Next, the DTE determiner 128 may be configured to repeatedly perform a process of determining a DTE based on the adjusted actual energy efficiency, determining one of a plurality of variable rates for each unit distance if the vehicle starts driving again after initialization of the rate, adjusting the actual energy efficiency based on the rate determined for each unit distance, and determining the DTE based on the adjusted actual energy efficiency.

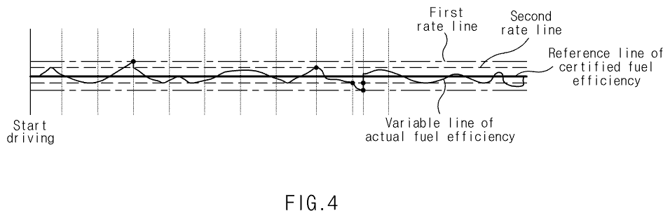

FIG. 4 shows a graph for describing a variable rate setting process of an example DTE control apparatus.

According to the present disclosure, it may be possible to set one certified energy efficiency and multiple variable rates based on the driving information of the vehicle, monitor actual energy efficiency for each unit distance in response to starting vehicle driving, and compare the monitored actual energy efficiency with the certified energy efficiency to determine one of the variable rates for each unit distance.

As shown in FIG. 4, according to the present disclosure, a change in actual energy efficiency according to a travel distance of a vehicle may be graphically expressed.

For example, according to the present disclosure, it may be possible to set the certified energy efficiency as a reference line, set first rate lines (also referred to as a first reference energy rate, for example, including a higher reference rate and a lower reference rate) parallel to upper and lower portions of the reference line to set an application range of the third rate, and set second rate lines (also referred to as a second reference energy rate, for example, including a higher reference rate and a lower reference rate) parallel to the upper and lower portions of the reference line between the reference line and the first rate lines to set application ranges of the first and second rates.

Herein, according to the present disclosure, as in No. 1 of FIG. 4, a third rate may be set to be applied if a variable line of the actual energy efficiency is in contact with the first rate line on a basis of the variable line of the actual energy efficiency that is variable based on the reference line of the certified energy efficiency.

Furthermore, according to the present disclosure, as in No. 2 of FIG. 4, a second rate may be set to be applied if the variable line of the actual energy efficiency is in contact with the second rate line.

Next, according to the present disclosure, as in No. 2 of FIG. 4, a first rate may be applied to be applied if the variable line of the actual energy efficiency is not in contact with either the first or second rate lines or is in contact with both of them.

Herein, the first rate may be a default rate, the second rate may be a rate corresponding to a stable behavior of the vehicle, and the third rate may be a rate corresponding to an unstable behavior of the vehicle. Furthermore, according to the present disclosure, a rate per unit distance may be determined. Next, according to the present disclosure, it may be possible to obtain an actual energy efficiency corresponding to a N-th unit distance, compare the actual energy efficiency corresponding to the N-th unit distance with the certified energy efficiency to determine a rate corresponding to the N-th unit distance, and in response to obtaining an actual energy efficiency corresponding to the (N+1)-th unit distance, compare the actual energy efficiency corresponding to the (N+1)-th unit distance with the certified energy efficiency to determine a rate corresponding to the (N+1)-th unit distance.

Herein, according to the present disclosure, it may be possible to determine one of a first rate corresponding to a default rate, a second rate corresponding to a rate if the vehicle is in a stable behavior, and a third rate corresponding to a rate if the vehicle is in an unstable behavior for each unit distance, based on logic according to a flip-flop logic circuit.

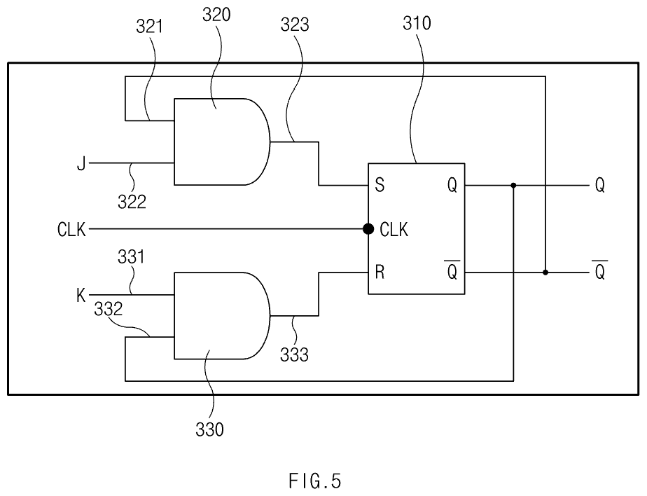

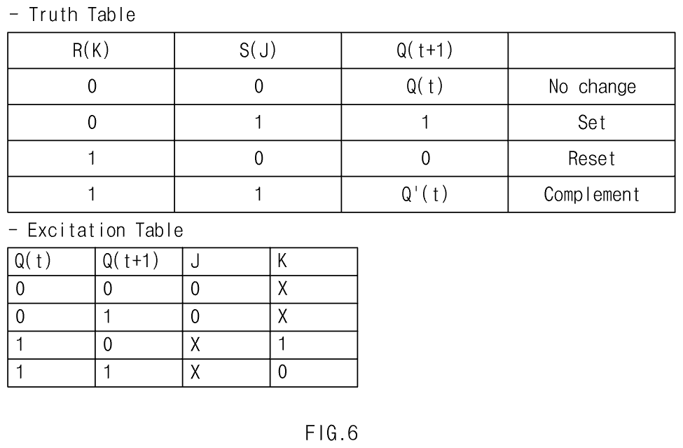

FIG. 5 and FIG. 6 show views for describing a logic of a flip-flop logic circuit for rate determination of an example DTE control apparatus.

For example, the flip-flop logic circuit may include an RS flip-flop 310 configured to output a signal for determining a rate, a first AND gate 320 connected to a first input terminal S of the RS flip-flop 310 and configured to output an output value according to an input value of the actual energy efficiency to the first input terminal S of the RS flip-flop, and a second AND gate 330 connected to a second input terminal R of the RS flip-flop 310 and configured to output an output value according to an input value of the actual energy efficiency to the second input terminal R of the RS flip-flop 310.

Herein, the RS flip-flop 310 may include the first input terminal S connected to an output terminal of the first AND gate 320, the second input terminal R connected to an output terminal of the second AND gate 330, a clock input terminal CLK into which a clock signal is input, a first output terminal Q that outputs a first signal as a signal for determining (e.g., selecting) a rate, and a second output terminal Q̅ that outputs a second signal, which is an inversion of the first signal, as the signal for determining the rate.

Furthermore, the first AND gate 320 may include a first input terminal 322 into which a first input value J of the actual energy efficiency is input, a second input terminal 321 connected to the second output terminal Q̅ of the RS flip-flop 310 and into which a second signal is input, and an output terminal 323 connected to the first input terminal S of the RS flip-flop 310.

The second AND gate 330 may include a first input terminal 331 to which a second input value K of the actual energy efficiency is input, a second input terminal 332 connected to the first output terminal Q of the RS flipflop 310 and to which a first signal is input, and an output terminal 333 connected to the second input terminal R of the RS flipflop 310.

For each unit distance where the variable line of the actual energy efficiency touches a first rate line (e.g., if the actual energy efficiency matches the first rate while the vehicle traverses the unit distance), the second input value K may be 1. For each unit distance where the variable line of the actual energy efficiency does not touch the first rate line (e.g., if the actual energy efficiency never matches the first rate while the vehicle traverses the unit distance), the second input value K may be 0. For each unit distance where the variable line of the actual energy efficiency touches a second rate line (e.g., if the actual energy efficiency matches the second rate while the vehicle traverses the unit distance), the first input value J may be 1. For each unit distance where the variable line of the actual energy efficiency never touches the second rate line (e.g., if the actual energy efficiency never matches the second rate while the vehicle traverses the unit distance), the first input value J may be 0.

For example, in FIG. 4, if the vehicle is first driven, the variable line of the actual energy efficiency does not touch both the first and second rate lines, so the first rate, which is the default rate, may be set to be applied.

In the instant case, in the flip-flop logic of FIG. 5, the first input value J of the actual energy efficiency may not be input to the first input terminal 322 of the first AND gate 320, and the second input value K of the actual energy efficiency may not be input to the first input terminal 331 of the second AND gate 330, so the first rate, which is the default rate, may be set to be applied.

As shown in FIG. 4, a third rate may be set to be applied (e.g., selected) if a variable line of the actual energy efficiency is in contact with the first rate line on a basis of the variable line of the actual energy efficiency that is variable based on the reference line of the certified energy efficiency.

In the instant case, in the flip-flop logic of FIG. 5, the second input value K of the actual energy efficiency may be input to the first input terminal 331 of the second AND gate 330 so a third rate, which corresponds to a rate of the vehicle when it is in an unstable behavior, may be set to be applied.

As shown in FIG. 4, a second rate may be set to be applied (e.g., selected) if the variable line of the actual energy efficiency is in contact with the second rate line.

In the flip-flop logic of FIG. 5, the first input value J of the actual energy efficiency may be input to the first input terminal 322 of the first AND gate 320 so a second rate corresponding to a rate if the vehicle is in a stable behavior of the vehicle may be set to be applied.

Furthermore, as shown in FIG. 4, a first rate may be applied (e.g., selected) if the variable line of the actual energy efficiency is in contact with both the first and second rate lines.

In the instant case, in the flip-flop logic of FIG. 5, the first input value J of the actual energy efficiency may be input to the first input terminal 322 of the first AND gate 320, and the second input value K of the actual energy efficiency may be input to the first input terminal 331 of the second AND gate 330, so a situation in which the energy efficiency changes significantly and abruptly may occur.

Herein, a rate complement signal may be turned on to perform rate initialization and set the first rate, which is the default rate, to be applied.

Accordingly, according to the present disclosure, it may be possible to determine the third rate for each unit distance if a variable line of the actual energy efficiency touches a first rate line at each unit distance based on an actual energy efficiency change graph according to the travel distance of the vehicle, which includes a reference line corresponding to the certified energy efficiency, first rate lines parallel to upper and lower portions of the reference line, and second rate lines positioned between the reference line and the first rate lines, determine the second rate for the unit distance if the variable line of the actual energy efficiency touches a second rate line, and determine the first rate for the unit distance if the variable line of the actual energy efficiency does not touch or touches both the first and second rate lines.

Herein, according to the present disclosure, it may be possible to adjust the actual energy efficiency to lower a current applied rate of the actual energy efficiency for the unit distance if the third rate is determined for the unit distance, adjust the actual energy efficiency to raise the current applied rate of the actual energy efficiency for the unit distance if the second rate is determined for the unit distance, and adjust the actual energy efficiency to maintain or change the current applied rate of the actual energy efficiency for the unit distance to a default rate if the first rate is determined for the unit distance.

For example, according to the present disclosure, it may be possible to adjust the actual energy efficiency to maintain or change a current applied rate of the actual energy efficiency to the default rate if the rate determined for each unit distance is the first rate, adjust the actual energy efficiency to increase the current applied rate of the actual energy efficiency if the rate determined for each unit distance is the second rate, and adjust the actual energy efficiency to decrease the current applied rate of the actual energy efficiency if the rate determined for each unit distance is the third rate.

Furthermore, according to the present disclosure, it may be possible to perform the rate initialization and delete the learning value if vehicle ignition is turned off.

Herein, the flip-flop logic circuit has volatile memory by nature, so a last set rate and a last energy efficiency value may be deleted, and this rate setting process may be repeated in response to re-driving.

That is, according to the present disclosure, it may be possible to determine a distance to empty (DTE) per unit distance based on the actual energy efficiency adjusted for each unit distance, and provide a total DTE corresponding to driving of a vehicle based on the DTE per unit distance.

Furthermore, according to the present disclosure, it may be possible to determine the DTE, and then remove and initialize the rate determined for each unit distance in response to ending vehicle driving.

Next, according to the present disclosure, it may be possible to repeatedly perform a process of determining one of a plurality of variable rates for each unit distance if the vehicle starts driving again after initialization of the rate, adjusting the actual energy efficiency based on the rate determined for each unit distance, and determining the DTE based on the adjusted actual energy efficiency.

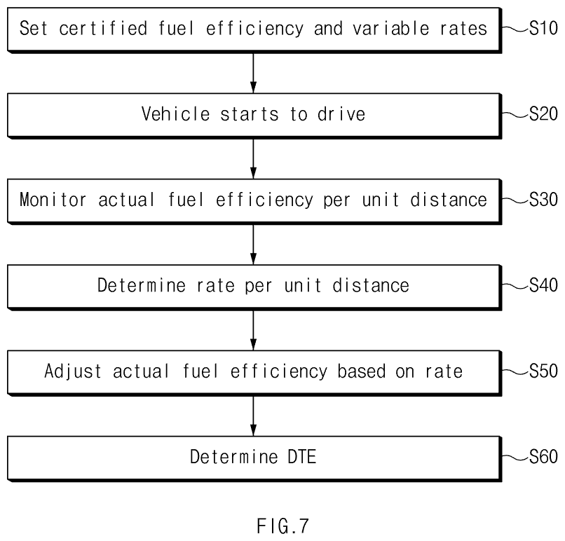

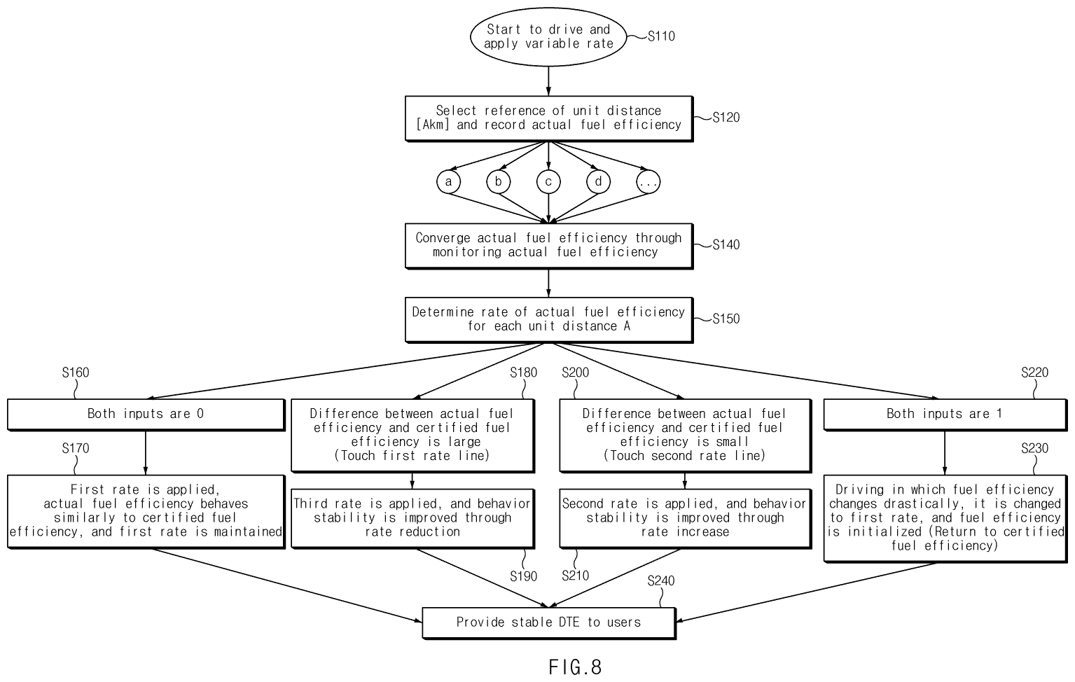

FIG. 7 and FIG. 8 each show a flowchart for describing a DTE control method for an example DTE control apparatus.

As shown in FIG. 7, according to the present disclosure, it may be possible to set one certified energy efficiency and multiple variable rates based on driving information of a vehicle (S10).

Herein, according to the present disclosure, it may be possible to set the certified energy efficiency based on a certified all-electric range (AER), which is a distance at which it can be driven, in a case where a battery is fully charged, and the actual available energy.

Furthermore, according to the present disclosure, it may be possible to set a plurality of variable rates including a first rate corresponding to a default rate, a second rate corresponding to a rate if the vehicle is in a stable behavior, and a third rate corresponding to a rate if the vehicle is in an unstable behavior, based on driving information of the vehicle.

Furthermore, according to the present disclosure, it may be possible to check whether the vehicle has started to drive (S20).

Next, according to the present disclosure, it may be possible to monitor actual energy efficiency per unit distance in response to starting vehicle driving (S30).

Herein, according to the present disclosure, it may be possible to check whether a travel distance of the vehicle reaches a (N−1)-th unit distance after the vehicle starts driving, record the actual energy efficiency for the (N−1)-th unit distance if the vehicle reaches the (N−1)-th unit distance, check whether the travel distance of the vehicle reaches a N-th unit distance, record the actual energy efficiency for the N-th unit distance if the vehicle reaches the N-th unit distance, and check whether a travel distance of the vehicle reaches a (N+1)-th unit distance, and record the actual energy efficiency for the (N+1)-th unit distance if the vehicle reaches the (N+1)-th unit distance.

Next, according to the present disclosure, it may be possible to determine one of a plurality of variable rates per unit distance by comparing the monitored actual energy efficiency and the certified energy efficiency (S40).

Herein, according to the present disclosure, it may be possible to determine one of a first rate corresponding to a default rate, a second rate corresponding to a rate if the vehicle is in a stable behavior, and a third rate corresponding to a rate if the vehicle is in an unstable behavior for each unit distance, based on logic according to a flip-flop logic circuit.

Furthermore, according to the present disclosure, it may be possible to determine the third rate for each unit distance if a variable line of the actual energy efficiency touches a first rate line at each unit distance based on an actual energy efficiency change graph according to the travel distance of the vehicle, which includes a reference line corresponding to the certified energy efficiency, first rate lines parallel to upper and lower portions of the reference line, and second rate lines positioned between the reference line and the first rate lines, determine the second rate for the unit distance if the variable line of the actual energy efficiency touches a second rate line, and determine the first rate for the unit distance if the variable line of the actual energy efficiency does not touch or touches both the first and second rate lines.

Furthermore, according to the present disclosure, it may be possible to adjust the actual energy efficiency based on the rate determined for each unit distance (S50).

Herein, according to the present disclosure, it may be possible to adjust the actual energy efficiency to maintain or change a current applied rate of the actual energy efficiency to the default rate if the rate determined for each unit distance is the first rate, adjust the actual energy efficiency to increase the current applied rate of the actual energy efficiency if the rate determined for each unit distance is the second rate, and adjust the actual energy efficiency to decrease the current applied rate of the actual energy efficiency if the rate determined for each unit distance is the third rate.

Next, according to the present disclosure, it may be possible to determine a distance to empty (DTE) based on the adjusted actual energy efficiency (S60).

Next, according to the present disclosure, it may be possible to determine the DTE and then, remove and initialize the rate determined for each unit distance in response to ending vehicle driving.

Herein, according to the present disclosure, it may be possible to repeatedly perform a process of determining one of a plurality of variable rates for each unit distance if the vehicle starts driving again after initialization of the rate, adjusting the actual energy efficiency based on the rate determined for each unit distance, and determining the DTE based on the adjusted actual energy efficiency.

As shown in FIG. 8, according to the present disclosure, it may be possible to apply a variable rate in response to starting vehicle driving (S110).

Furthermore, according to the present disclosure, it may be possible to monitor and record the actual energy efficiency for each unit distance in a case where the unit distance is A km (S120).

Next, according to the present disclosure, after converging the actual energy efficiency recorded for each unit distance (S140), it may be possible to determine the rate of the actual energy efficiency for each unit distance A km (S150).

Next, according to the present disclosure, in the flip-flop logic of FIG. 5, if an actual energy efficiency input value of the first AND gate is 0 and an actual energy efficiency input value of the second AND gate is 0 (S160), the first rate, which is the default rate, may be set to be applied to maintain the actual energy efficiency at the first rate that behaves similarly to the certified energy efficiency (S170).

Furthermore, according to the present disclosure, in a case where a variable line of the actual energy efficiency comes into contact with a first rate line and a difference between the actual energy efficiency and the certified energy efficiency is large (e.g., above a threshold value) (S180), the third rate may be set to be applied (e.g., selected) to improve behavior stability through rate reduction (S190).

Furthermore, according to the present disclosure, as shown in FIG. 4, in a case where the variable line of the actual energy efficiency comes into contact with a second rate line and a difference between the actual energy efficiency and the certified energy efficiency is small (e.g., below a threshold value) (S200), the second rate may be set to be applied (e.g., selected) to improve the behavior stability through rate increase (S210).

Furthermore, according to the present disclosure, in the flip-flop logic of FIG. 5, if an actual energy efficiency input value of the first AND gate is 1 and an actual energy efficiency input value of the second AND gate is 1 (S220), a driving situation may occur in which the energy efficiency changes drastically, so rate initialization may be set to be performed and the first rate, which is the default rate, may be set to be applied (S230).

Next, according to the present disclosure, it may be possible to determine a distance to empty (DTE) per unit distance based on the actual energy efficiency adjusted for each unit distance, and provide a total DTE corresponding to driving of a vehicle based on the DTE per unit distance (S240).

As such, according to the present disclosure, if a vehicle starts driving, a DTE with high accuracy and stability may be provided by monitoring actual energy efficiency per unit distance to determine a rate, and by adjusting the actual energy efficiency based on the rate to determine the DTE, thereby enhancing user stability and satisfaction.

Furthermore, according to the present disclosure, actual energy efficiency of a user may be monitored by applying a flip-flop logic, which is a logic circuit, and a variable rate applied to the logic circuit according to a behavior of the actual energy efficiency may be applied to a rate that suits a user's driving pattern, thereby improving the accuracy of a DTE and providing a stable behavior.

According to the present disclosure, optimized behavior stability of a DTE that can resolve customer complaints about inaccuracy of the DTE may also be provided by predicting the DTE in consideration of various driving patterns of a customer.

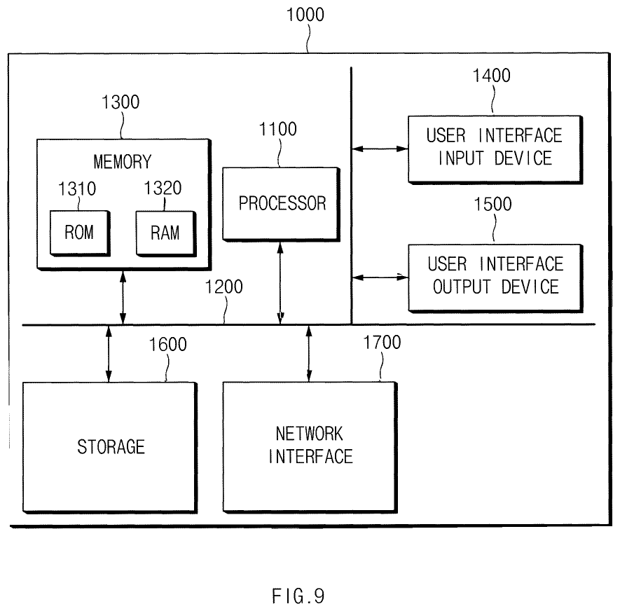

FIG. 9 shows an example computing system for a vehicle.

Referring to FIG. 9, the computing system 1000 includes at least one processor 1100 connected through a bus 1200, memory 1300, a user interface input device 1400, a user interface output device 1500, and a storage 1600, and a network interface 1700. The processor 1100 may be a central processing unit (CPU) or a semiconductor device that performs processing on commands stored in the memory 1300 and/or the storage 1600. The memory 1300 and the storage 1600 may include various types of volatile or nonvolatile storage media. For example, the memory 1300 may include a read-only memory (ROM) and a random access memory (RAM).

Accordingly, steps of a method or algorithm described in connection with the example embodiments included herein may be implemented with hardware, one or more software modules, or a combination of the two, executed by the processor 1100. The software module may reside in a storage medium (i.e., the memory 1300 and/or the storage 1600) such as a RAM, a flash memory, a ROM, an EPROM, an EEPROM, a register, a hard disk, a removable disk, and a CD-ROM.

An exemplary storage medium is coupled to the processor 1100, which can read information from and write information to the storage medium. Alternatively, the storage medium may be integrated with the processor 1100. The processor and the storage medium may reside within an application specific IC (ASIC). The ASIC may reside within a user terminal. Alternatively, the processor and the storage medium may reside as separate components within the user terminal.

The above description is merely illustrative of the technical idea of the present disclosure, and those skilled in the art to which the present disclosure pertains may make various modifications and variations without departing from the essential characteristics of the present disclosure.

Therefore, the example embodiments disclosed in the present disclosure are not intended to limit the technical ideas of the present disclosure, but to explain them, and the scope of the technical ideas of the present disclosure is not limited by these embodiments. The protection range of the present disclosure should be interpreted by the claims below, and all technical ideas within the equivalent range should be interpreted as being included in the scope of the present disclosure.

1. A distance to empty (DTE) control apparatus comprising:
an interface where driving information of a vehicle is input; and
a processor configured to determine a DTE of the vehicle,
wherein the processor is configured
to set one certified fuel efficiency and multiple variable rates based on the driving information of the vehicle, monitor actual fuel efficiency for each unit distance in response to starting vehicle driving, compare the monitored actual fuel efficiency with the certified fuel efficiency to determine one of the variable rates for each unit distance, adjust the actual fuel efficiency based on the rate determined for each unit distance, and determine the DTE based on the adjusted actual fuel efficiency.

2. The DTE control apparatus of claim 1, wherein
the processor is configured
to set the certified fuel efficiency based on a certified all electric range (AER), which is a distance at which it is to be driven, in a case where a battery is fully charged, and actual available energy.

3. The DTE control apparatus of claim 1, wherein
the processor is configured
to set a plurality of variable rates including a first rate corresponding to a default rate, a second rate corresponding to a rate in response to a case where the vehicle is in a stable behavior, and a third rate corresponding to a rate in response to a case where the vehicle is in an unstable behavior, based on the driving information of the vehicle.

4. The DTE control apparatus of claim 1, wherein
the processor is configured
to check whether a travel distance of the vehicle reaches a (N−1)^{th} unit distance after the vehicle starts driving in a case of monitoring the actual fuel efficiency, record the actual fuel efficiency for the (N−1)^{th} unit distance in response to a case where the vehicle reaches the (N−1)^{th} unit distance, check whether a travel distance of the vehicle reaches a N^{th} unit distance, record the actual fuel efficiency for the N^{th} unit distance in response to a case where the vehicle reaches the N^{th} unit distance, and check whether a travel distance of the vehicle reaches a (N+1)^{th} unit distance, and record the actual fuel efficiency for the (N+1)^{th} unit distance in response to a case where the vehicle reaches the (N+1)^{th} unit distance.

5. The DTE control apparatus of claim 1, wherein
the processor is configured
to determine one of a first rate corresponding to a default rate, a second rate corresponding to a rate in response to a case where the vehicle is in a stable behavior, and a third rate corresponding to a rate in response to a case where the vehicle is in an unstable behavior for each unit distance, based on logic according to a flip-flop logic circuit, in a case of determining a rate for each unit distance.

6. The DTE control apparatus of claim 5, wherein
the flip-flop logic circuit is configured
to include an RS flip-flop configured to output a signal for determining the rate;
a first AND gate connected to a first input terminal of the RS flip-flop to output an output value according to an input value of the actual fuel efficiency to the first input terminal of the RS flip-flop; and
a second AND gate connected to a second input terminal of the RS flip-flop to output an output value according to an input value of the actual fuel efficiency to the second input terminal of the RS flip-flop.

7. The DTE control apparatus of claim 5, wherein
the processor is configured
to determine the third rate for each unit distance in response to a case where a variable line of the actual fuel efficiency touches a first rate line at each unit distance based on an actual fuel efficiency change graph according to a travel distance of the vehicle, which includes a reference line corresponding to the certified fuel efficiency, first rate lines parallel to upper and lower portions of the reference line, and second rate lines positioned between the reference line and the first rate lines, determine the second rate for the unit distance in response to a case where the variable line of the actual fuel efficiency touches a second rate line, and determine the first rate for the unit distance in response to a case where the variable line of the actual fuel efficiency does not touch or touches both the first and second rate lines, in a case of determining a rate for each unit distance.

8. The DTE control apparatus of claim 1, wherein
the processor is configured
to adjust the actual fuel efficiency to maintain or change a current reflection rate of the actual fuel efficiency to the default rate in response to a case where the rate determined for each unit distance is a first rate,
adjust the actual fuel efficiency to increase the current reflection rate of the actual fuel efficiency in response to a case where the rate determined for each unit distance is a second rate, and
adjust the actual fuel efficiency to decrease the current reflection rate of the actual fuel efficiency in response to a case where the rate determined for each unit distance is a third rate.

9. The DTE control apparatus of claim 1, wherein
the processor is configured
to determine the DTE, and then remove and initialize the rate determined for each unit distance in response to ending the vehicle driving.

10. The DTE control apparatus of claim 9, wherein
the processor is configured
to repeatedly perform a process of determining one of a plurality of variable rates for each unit distance in response to a case where the vehicle starts driving again after initialization of the rate, adjusting the actual fuel efficiency based on the rate determined for each unit distance, and determining the DTE based on the adjusted actual fuel efficiency.

11. A vehicle system comprising:
a display device configured to display a distance to empty (DTE) corresponding to driving information; and
a DTE control apparatus configured to determine the DTE of the vehicle,
wherein the DTE control apparatus is configured
to set one certified fuel efficiency and multiple variable rates based on the driving information of the vehicle, monitor actual fuel efficiency for each unit distance in response to starting vehicle driving, compare the monitored actual fuel efficiency with the certified fuel efficiency to determine one of the variable rates for each unit distance, adjust the actual fuel efficiency based on the rate determined for each unit distance, and determine the DTE based on the adjusted actual fuel efficiency.

12. A distance to empty (DTE) control method for a DTE control apparatus which determines a DTE of a vehicle, the method comprising:
setting, by a processor, one certified fuel efficiency and multiple variable rates based on driving information of the vehicle;
monitoring, by the processor, actual fuel efficiency per unit distance in response to starting driving of the vehicle;
comparing, by the processor, the monitored actual fuel efficiency with the certified fuel efficiency to determine one of the variable rates for each unit distance;
adjusting, by the processor, the actual fuel efficiency based on the rate determined for each unit distance; and
determining, by the processor, the DTE based on the adjusted actual fuel efficiency.

13. The DTE control method of claim 12, wherein
the setting of the certified fuel efficiency
is performed by setting the certified fuel efficiency based on a certified all electric range (AER), which is a distance at which it is to be driven, in a case where a battery is fully charged, and actual available energy.

14. The DTE control method of claim 12, wherein
the setting of the variable rates
is performed by setting a plurality of variable rates including a first rate corresponding to a default rate, a second rate corresponding to a rate in response to a case where the vehicle is in a stable behavior, and a third rate corresponding to a rate in response to a case where the vehicle is in an unstable behavior, based on the driving information of the vehicle.

15. The DTE control method of claim 12, wherein
the monitoring of the actual fuel efficiency
is performed by checking whether a travel distance of the vehicle reaches a (N−1)^{th} unit distance after the vehicle starts driving in a case of monitoring the actual fuel efficiency, record the actual fuel efficiency for the (N−1)^{th} unit distance in response to a case where the vehicle reaches the (N−1)^{th} unit distance, check whether a travel distance of the vehicle reaches a N^{th} unit distance, record the actual fuel efficiency for the N^{th} unit distance in response to a case where the vehicle reaches the N^{th} unit distance, and check whether a travel distance of the vehicle reaches a (N+1)^{th} unit distance, and record the actual fuel efficiency for the (N+1)^{th} unit distance in response to a case where the vehicle reaches the (N+1)^{th} unit distance.

16. The DTE control method of claim 12, wherein
the determining of the rate for each unit distance
is performed by determining one of a first rate corresponding to a default rate, a second rate corresponding to a rate in response to a case where the vehicle is in a stable behavior, and a third rate corresponding to a rate in response to a case where the vehicle is in an unstable behavior for each unit distance based on logic according to a flip-flop logic circuit, in a case of determining a rate for each unit distance.

17. The DTE control method of claim 16, wherein
the determining of the rate for each unit distance
is performed by determining the third rate for each unit distance in response to a case where a variable line of the actual fuel efficiency touches a first rate line at each unit distance based on an actual fuel efficiency change graph according to a travel distance of the vehicle, which includes a reference line corresponding to the certified fuel efficiency, first rate lines parallel to upper and lower portions of the reference line, and second rate lines positioned between the reference line and the first rate lines, determine the second rate for the unit distance in response to a case where the variable line of the actual fuel efficiency touches a second rate line, and determine the first rate for the unit distance in response to a case where the variable line of the actual fuel efficiency does not touch or touches both the first and second rate lines, in a case of determining a rate for each unit distance.

18. The DTE control method of claim 12, wherein
the adjusting of the actual fuel efficiency
is performed by adjusting the actual fuel efficiency to maintain or change a current reflection rate of the actual fuel efficiency to the default rate in response to a case where the rate determined for each unit distance is a first rate,
adjusting the actual fuel efficiency to increase the current reflection rate of the actual fuel efficiency in response to a case where the rate determined for each unit distance is a second rate, and
adjusting the actual fuel efficiency to decrease the current reflection rate of the actual fuel efficiency in response to a case where the rate determined for each unit distance is a third rate.

19. The DTE control method of claim 12, further comprising
determining, by the processor, the DTE, and then removing and initializing the rate determined for each unit distance in response to ending the vehicle driving.

20. The DTE control method of claim 19, wherein
the processor is configured
to repeatedly perform a process of determining one of a plurality of variable rates for each unit distance in response to a case where the vehicle starts driving again after initialization of the rate, adjusting the actual fuel efficiency based on the rate determined for each unit distance, and determining the DTE based on the adjusted actual fuel efficiency.
